(19) United States
(12) Patent Application Publication
(10) Pub. No.: US 2022/0149238 A1
(43) Pub. Date: May 12, 2022

(54) RGB FULL-COLOR InGaN-BASED LED AND METHOD FOR PREPARING THE SAME

(71) Applicant: Hsiao-Lei WANG, Taoyuan City, Taiwan (CN)

(72) Inventors: Hsiao-Lei WANG, Taoyuan City, Taiwan (CN); Chia-Huan LIU, Taoyuan City, Taiwan (CN); Kao-Mei SUNG, Taoyuan City, Taiwan (CN)

(21) Appl. No.: 17/439,095

(22) PCT Filed: Mar. 20, 2020
(86) PCT No.: PCT/CN2020/080291

§ 371 Date: Sep. 14, 2021

(30) Foreign Application Priority Data
Mar. 28, 2019 (CN) 201910240892.5

(51) Int. Cl. H01L 33/32; H01L 33/00

(52) U.S. Cl. CPC H01L 33/32; H01L 33/0075

(57) ABSTRACT

An RGB full-color InGaN-based LED, a substrate material is covered with a lattice-matched 2D material ultra-thin layer in a surface as an intermediate layer, and an InGaN-based material epitaxial layer is grown on the 2D material ultra-thin layer; the 2D material ultra-thin layer is formed by a single material or formed by stacking more than one material. It can realize high-quality and high In content InₓGa₁₋ₓN epitaxy on the currently available substrate surface, such that high-efficiency direct green/red light emitting diodes can be achieved, and the epitaxy and assembly processes can be simplified.

### TECHNICAL FIELD

The present disclosure relates to the technical field of LEDs, in particular, to an RGB full-color InGaN-based LED prepared by introducing an ultra-thin intermediate layer of 2D materials, and a method for preparing the same.

### BACKGROUND

In the manufacturing process of Micro-LED displays (Displays), red, green and blue (RGB) three primary color light-emitting diodes are used to form the pixels of the unit. At present, the main manufacturing technology needs to mix nitrides and phosphides series of light-emitting diodes, such that it can meet the needs of the three primary colors. When light-emitting diodes of different material systems are mixed, different heating and attenuation characteristics directly affect the quality of the image presentation; different electrical driving characteristics directly lead to the complexity of the display module drive design. Therefore, if the direct light-emitting RGB (red, green, and blue) three primary color light-emitting diodes are realized on the same material system, it will not only help solve the above problems, but also reduce the complexity of the process and the energy efficiency loss caused by the conversion due to the omission of the color-to-light conversion mechanism such as phosphors, such that it will be beneficial to the development of Micro LED technology.

Indium gallium nitride InₓGa₁₋ₓN epitaxy material is currently one of the material systems for making mainstream blue light emitting diodes. Theoretically, the entire visible light emission range can be covered by the indium gallium solid solution ratio control. Indium gallium nitride benefits from direct energy gap characteristic, and is also expected to have better luminous efficiency, especially the blue mass production technology is proficient, so it has received more attention than other material systems, in the production of direct red, green and blue light-emitting diodes (RGB direct LED) with similar control conditions and good performance has great potential. However, at present, the green and red light-emitting diodes of InₓGa₁₋ₓN epitaxial materials are facing technical bottlenecks. To achieve the appropriate light-emitting bands of green and red light, the In content ratio of InₓGa₁₋ₓN series epitaxy needs to be increased. However, it faces obstacles such as poor epitaxial quality. The main reason is that although InₓGa₁₋ₓN has solid solubility in the entire composition (x) range, the gap between In and Ga ion radii is large, making the solid solubility more sensitive to stress conditions and the probability of phase separation is higher. When the In content increases, the lattice constant of the epitaxial layer increases, and the strain caused by the mismatch with the substrate material also increases, resulting in InₓGa₁₋ₓN solid solubility is impacted and the phase separation of InN occurs due to the impact, and the originally expected light-emitting characteristics are severely impacted. Therefore, one of the main methods to solve the development of green and red direct LED technology is to find an epitaxial substrate material with a suitable lattice constant. Referring to FIG. 1, it is a graph of the band gap energy-lattice constant-wavelength relationship of indium gallium nitride.

Zinc oxide (ZnO) single crystal material is a more suitable substrate material candidate in the previous item in terms of crystal structure, thermal properties, and lattice constant, which attracts researchers' interest. However, zinc oxide is not widely used in the technical field today. The main reason is that zinc oxide has high chemical activity and is easily corroded by hydrogen-containing substances in the subsequent epitaxy process, resulting in poor epitaxial layer quality, as shown in FIG. 2. During the epitaxial process, hydrogen etches the zinc oxide substrate while zinc rapidly diffuses into the epitaxial layer, resulting in poor epitaxial quality. Adjusting the process can improve the epitaxial quality, but diffusion of zinc and oxygen still occurs, and they dope into the crystal grains of the light-emitting diode, causing light emission characteristics fail to meet expectations, making this structure unable to meet actual market demand.

TABLE 1

| | | | | Thermal Expansion |
|---|---|---|---|---|
| | Crystal | Lattice Constant | | Coefficient |
| Material | Structure | a | c | (*10⁻⁶ * K⁻¹) |
| Gallium Nitride | Wurtzite | 0.31885 | 0.5185 | αₐ 5.59 |
| (GaN) | | | | α_{c} 3.17 |
| Indium Nitride | Wurtzite | 0.3545 | 0.5703 | αₐ 3.8 |
| (InN) | | | | α_{c} 2.9 |
| Zinc Oxide | Wurtzite | 0.32496 | 0.52065 | αₐ 4.31 |
| (ZnO) | | | | α_{c} 2.49 |
| Sapphire | Rhombohedral | 0.4765 | 1.2982 | αₐ 6.66 |
| | | | | α_{c} 5 |
| Silicon | Diamond | 0.5431 | | 2.6 |
| (Si) | | | | |

As shown in Table 1, according to the current technology, whether the substrate materials adopted are single-crystal sapphire (Sapphire), single-crystal zinc oxide (ZnO), or even single-crystal gallium nitride (GaN) substrates and the like, they cannot be successfully to produce direct green and red light-emitting diodes made of InₓGa₁₋ₓN epitaxial materials with practical applications. It is very difficult to realize the three-primary color RGB LED chip with the same material system, direct light emission, and high performance on the micro LED technology.

In view of this, the French company Soitec announced in 2017 that it has developed a substrate material suitable for the above-mentioned purposes. In the same year, it released the direct green LED successfully produced using the substrate. The company released that the developed substrate crystal has the lattice constant reaching as high as 0.3205 nanometers (nm). In 2018, the company released a direct red LED successfully produced using the substrate. The highest substrate lattice constant released by the company remains unchanged at 0.3205 nanometers (nm). The company's substrate development has not only achieved specific results, but also proved that the substrate lattice constant is the key to the successful realization of InₓGa₁₋ₓN direct green/red LEDs. However, as shown in FIG. 3, the substrate technology uses complex and complicated manufacturing processes and high manufacturing costs, such that it may hinder widespread adoption by the market.

Two-dimensional (2D) materials are a rapidly developing emerging field. The first and most well-known material in the 2D material family that attracted a large amount of R&D investment is graphene, its two-dimensional layered structure has a special or excellent physical/chemical/mechanical/optical properties. There is no strong bond between the layers. Only van der Waals forces are present for combination. This also means that there are no dangling bonds on the surface of the layered structure. At present, graphene has been confirmed that it has a wide and excellent application potential, graphene research and development work is generally carried out around the world, and it also drives the research and development of more 2D materials, including hexagonal Boron Nitride (hBN), transition metal dichalcogenides (TMDs) and black phosphorus and the like, they are also the 2D material family that have accumulated more research and development results. As shown in FIG. 4 and FIG. 5, the above materials have their own specific material characteristics and application potentials, and the development of related materials manufacturing technology continues actively promoting. In addition to excellent photoelectric properties, graphene, hBN, and MoS₂, one of the TMDs materials, are all considered to have excellent diffusion barrier properties, as well as varying degrees of high temperature stability. In particular, hBN has excellent chemical inertness and high temperature oxidation resistance.

Due to the nature of the above-mentioned layered structure and the combination of van der Waals forces between layers, the technical feasibility of making two or more materials in the 2D material family into layered stacked hetero-structures is greatly improved. In addition to the combination of different characteristics, the hetero-structures make it possible to create new application characteristics or make new components. Currently, research and development in the field of optoelectronics and semiconductors is quite active. FIGS. 6a and 6b are schematic diagrams showing mechanical composition lamination. FIGS. 7a and 7b are schematic diagrams showing physical or chemical vapor deposition.

The van der Waals force bonding characteristics of 2D materials have also attracted attention for the use of epitaxial substrates applied to traditional 3D materials. The focus is on the crystal structure, lattice constant, and coefficient of thermal expansion (CTE) of epitaxial materials in epitaxial technology must match the substrate material very well, but in reality, it often encounters the lack of suitable substrate materials as mentioned by the subject of the present disclosure, or the ideal substrate material is expensive or difficult to obtain. At this time, 2D materials are provided as another solution for hetero-epitaxial substrates, that is the so-called van der Waals Epitaxy. The mechanism that van der Waals epitaxy may be beneficial to heterogeneous epitaxy comes from that the direct chemical bond of the traditional epitaxial interface is replaced by van der Waals force bonding, which will relieve the stress or strain energy from the lattice and thermal expansion mismatch in the epitaxial process to a certain extent, so as to improve the quality of the epitaxial layer, in other words, through the introduction of 2D materials and van der Waals epitaxy, certain hetero-epitaxial techniques that were not in practice can be made possible. Related research also pointed out that when the above-mentioned 2D materials are stacked on each other with heterogeneous structures, the mutual force is dominated by Van der Waals forces; while the epitaxy of 3D materials is carried out on 2D materials, due to the dangling bonds of 3D materials on the interface exists and the dangling bond also contributes to the bonding force of the interface, this epitaxy is not pure van der Waals Epitaxy or can be more accurately regarded as Quasi van der Waals Epitaxy. No matter what the situation is, the matching degree of the lattice and thermal expansion undoubtedly still plays a certain role in the final epitaxial quality. Both the 2D material intermediate layer and the substrate material contribute to the overall matching degree. The above-mentioned 2D layered material has a hexagon or honeycomb structure, and is considered structurally compatible with Wurtzite and Zinc-Blende structural materials during the epitaxy. The main epitaxial materials in the related fields of the present disclosure belong to this type of structure. As the InₓGa₁₋ₓN epitaxial layer of direct green, red LED, it belongs to the Wurtzite structure. In fact, as shown in FIG. 8, high quality gallium nitride (GaN) epitaxial layers have been successfully implemented on different substrate materials with 2D materials (mainly graphene) as intermediate layers, including silicon carbide (SiC), sapphire, and fused silica (SiO₂), etc. The application feasibility of van der Waals Epitaxy or Quasi van der Waals Epitaxy technology has received many verifications.

### SUMMARY

The present disclosure is intended to provide an RGB full-color InGaN-based LED, and a method for preparing the same, by using an introduction of 2D material ultra-thin layer, directly emitting RGB (red, green and blue) three primary color light-emitting diodes on the same material system.

In order to achieve the above objective, the solution of the present disclosure is:

An RGB full-color InGaN-based LED,

a substrate material is covered with a lattice-matched 2D material ultra-thin layer in a surface as an intermediate layer, and an InGaN-based material epitaxial layer is grown on the 2D material ultra-thin layer; the 2D material ultra-thin layer is formed by a single material or formed by stacking more than one material.

The 2D material is hexagonal Boron Nitride (hBN), graphene, hBNC, WS₂, WSe₂, MoS₂ or MoSe₂. The 2D material ultra-thin layer has a thickness that ranges from 0.5 nm to 1000 nm.

The 2D material ultra-thin layer is a single layer, such as WSe₂, or MoSe₂.

The 2D material ultra-thin layer is a composite layer structure; a top layer is made of a 2D material that matches the InGaN lattice, such as WSe₂, or MoSe₂; and a bottom layer is made of a 2D material with good barrier effect, such as hexagonal Boron Nitride (hBN), graphene.

The substrate is single-crystal substrate, such as sapphire, zinc oxide (ZnO), monocrystalline silicon (Si), SiC, GaN; the substrate is material, such as ceramic or glass, etc.

A metal catalytic layer is added between the substrate and the intermediate layer, the metal catalytic layer has a total thickness that ranges from 0.5 nm to 3000 nm, and the metal catalytic layer comprises Fe, Co, Ni, Au, Ag, Cu, W, Mo, Ru or Pt.

A method for preparing an RGB full-color InGaN-based LED, wherein epitaxial steps for the InGaN-based material and the substrate are as follows:

Step 1, performing epitaxial growth grade polishing on the substrate (wafer) material, and preparing for subsequent manufacturing procedures through appropriate pre-treatment (including wafer cleaning);

Step 2, covering a lattice-matched 2D material on a surface of the substrate (wafer) material as an intermediate layer for the epitaxial InGaN material by using van der Waals Epitaxy or quasi-van der Waals Epitaxy technology;

Step 3, growing an epitaxial layer of InGaN-based material on the intermediate layer using van der Waals Epitaxy or quasi-van der Waals Epitaxy technology.

In Step 2, a single layer or a composite layer 2D material is covered on the surface of the substrate material.

In Step 2, 2D material covering the surface of the substrate material adopts the process, such as growth, deposition, transfer and coating etc. A total thickness of the single layer or the composite layers ranges from 0.5 nm to 1000 nm.

Between Step 1 and Step 2, according to growth requirements of 2D materials, in a manufacturing process such as a metal catalyst layer is added at a proper time, a total thickness of the metal catalytic layer ranges from 0.5 nm to 3000 nm. The growth or deposition process of the 2D material covering the surface of the substrate material may require a metal catalyst layer including Fe, Co, Ni, Au, Ag, Cu, W, Mo, Ru, or Pt to be grown or deposited on the surface of the substrate first, and may require heat treatment process.

Between Step 2 and Step 3, according to epitaxial quality requirements in Step 3, the 2D material intermediate layer in Step 2 is lithographically divided into domains at a proper time, each of the domains has a size is from 1*1 mm² to 1000*1000 mm².

After adopting the above solution, the present disclosure uses 2D material to cover the surface of the substrate material as the intermediate layer for InₓGa₁₋ₓN epitaxy, and performs van der Waals epitaxy or quasi-van der Waals epitaxy, making the stress or strain energy from the lattice and thermal expansion mismatch in the epitaxy process to be relieved for a certain degree, and high quality and high In content InₓGa₁₋ₓN epitaxy can be achieved on the currently available substrate surface, and direct green/red LED with high efficiency can be obtained.

The present disclosure can replace the InGaN template substrate developed by Soitec, it can realize direct light-emitting RGB (red, green, and blue) three primary color light-emitting diodes on the same material system, simplify the epitaxial and component processes, making the selection of substrate materials more widely possible. The manufacturing cost is low, and it is conducive to market promotion and application.

### BRIEF DESCRIPTION OF DRAWINGS

FIG. 1 is a graph illustrating a band gap energy-lattice constant-wavelength relationship of conventional indium gallium nitride;

FIG. 2 is a schematic diagram illustrating a conventional zinc oxide substrate being corroded during the epitaxy process;

FIG. 3 is a manufacturing process diagram illustrating a substrate developed by a conventional French company Soitec;

FIG. 4 is a schematic diagram illustrating a structure of a conventional two-dimensional material transition metal dichalcogenides (TMDs);

FIG. 5 is a schematic diagram illustrating a structure of the conventional two-dimensional material hexagonal Boron Nitride (hBN);

FIGS. 6a and 6b are schematic diagrams illustrating conventional mechanical composition laminations;

FIGS. 7a and 7b are schematic diagrams illustrating conventional physical or chemical vapor deposition;

FIG. 8 is a schematic diagram illustrating the structure of conventional gallium nitride/graphene/silicon carbide;

FIG. 9 is a schematic structural diagram illustrating Embodiment 1 of the present disclosure;

FIG. 10 is a schematic structural diagram illustrating Embodiment 2 of the present disclosure.

In the drawings:

1, substrate; 2, epitaxial layer; 3, 2D material ultra-thin layer; 31, top layer; 32, bottom layer; 4, metal catalytic layer.

### DESCRIPTION OF EMBODIMENTS

The present disclosure will be further described in detail below with reference to the drawings and specific embodiments.

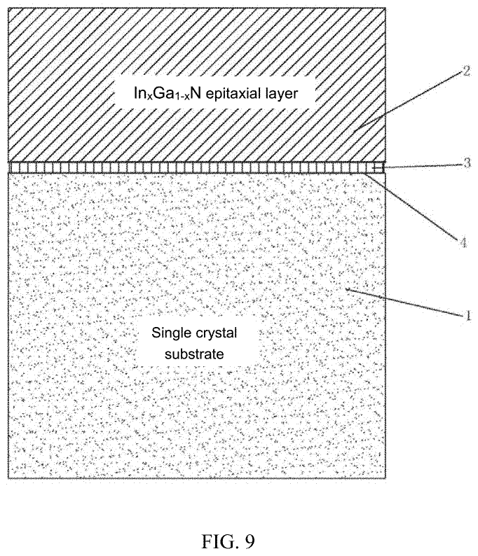

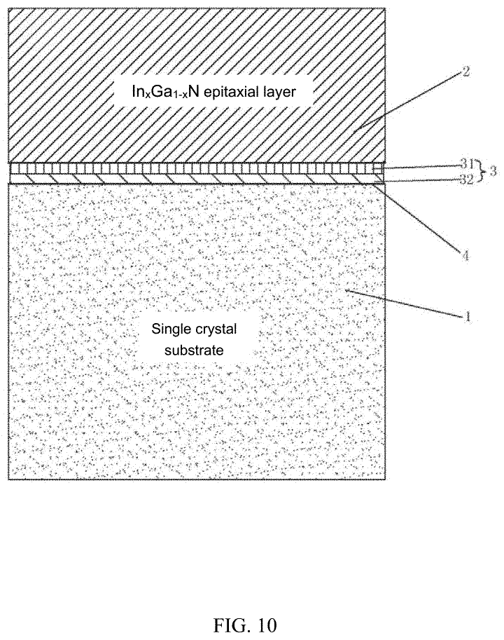

As shown in FIG. 9 and FIG. 10, in terms of structure, the RGB full-color InGaN-based LED provided in the present disclosure may be covered with a lattice-matched 2D material ultra-thin layer 3 on the material surface of the substrate 1 as an intermediate layer for InₓGa₁₋ₓN epitaxy, and the InGaN-based material epitaxial layer 2 grows on the 2D material ultra-thin layer 3, the 2D material ultra-thin layer 3 may be composed of a single material as shown in FIG. 9 or formed by laminating more than one material as shown in FIG. 10. The 2D material ultra-thin layer 3 and the InGaN-based material epitaxial layer 2 and the substrate 1 use lattice matching or van der Waals Epitaxy (VDWE) to achieve stress relaxation.

Among them, the substrate 1 of the present disclosure may be a single crystal substrate, including but not limited to single crystal materials such as sapphire, zinc oxide ZnO, single crystal silicon Si, SiC, GaN, etc. Alternatively, the substrate 1 may be a material such as ceramics or glass. The 2D material of the present disclosure can use hexagonal Boron Nitride (hBN), graphene, hBNC, WS₂, WSe₂, MoS₂ or MoSe₂. The thickness of the 2D material ultra-thin layer 3 may range from 0.5 nm to 1000 nm.

The 2D material ultra-thin layer 3 shown in FIG. 9 is a single material with good lattice matching, such as WSe₂ or MoSe₂.

The 2D material ultra-thin layer 3 shown in FIG. 10 is a composite intermediate layer. The top layer 31 may be made of a 2D material with good lattice matching with InGaN, such as WSe₂ or MoSe₂, and the bottom layer 32 may be made of a 2D material with good barrier effect, such as hexagonal Boron Nitride (hBN), graphene. The lattice constants of various materials may be shown in Table 2.

TABLE 2

| Material | Lattice constant a (nm) |
|---|---|
| hexagonal Boron Nitride (hBN) | 0.25 |
| Graphene | 0.246 |
| WSe₂ | 0.3297 |
| MoSe₂ | 0.3283 |

The 2D material ultra-thin layer of the bottom layer 32 acts as a barrier to prevent defects in the substrate material from causing damage to the quality of the epitaxial layer and component performance. The defects in the substrate may include point defects (such as oxygen ions or other impurities) and line defects (such as dislocations).

In order to obtain a better structure, the present disclosure can add a metal catalytic layer 4 on the surface of the 2D material covering the substrate 1. The metal catalytic layer 4 can include Fe, Co, Ni, Au, Ag, Cu, W, Mo, Ru or Pt, etc. The metal catalytic layer 4 may be grown or deposited on the surface of the substrate 1 first, and a heat treatment process may also be required. The total thickness of the metal catalytic layer 4 may range from 0.5 nm to 3000 nm.

The present disclosure also provides a method for preparing an RGB full-color InGaN-based LED, the epitaxy steps for InGaN-based materials and substrate may be as follows:

In Step 1, performing epitaxial-ready growth grade polishing on the substrate 1 (wafer) material, and preparing for subsequent manufacturing procedures through appropriate pre-treatment (including wafer cleaning).

After step 1 and before step 2, manufacturing processes such as the metal catalytic layer 4 can be added in due course according to the growth requirements of the 2D material. The growth or deposition process of the 2D material covering the surface of the substrate 1 may require a metal catalytic layer 4 including Fe, Co, Ni, Au, Ag, Cu, W, Mo, Ru, or Pt to be grown or deposited on the surface of the substrate 1 in advance, heat treatment process may also be needed. The total thickness of the metal catalytic layer 4 ranges from 0.5 nm to 3000 nm.

Step 2, covering a lattice-matched 2D material on the surface of the substrate material as an intermediate layer for the epitaxial InGaN material by using van der Waals Epitaxy or quasi-van der Waals Epitaxy technology. It can be covered by a single layer or a composite layer 2D material ultra-thin layer 3. The 2D material covering the surface of the substrate 1 can adopt existing processes, including growth, deposition, transfer, coating, etc., as well as related necessary pre-treatment and post-treatment processes. The total thickness of a single layer or multiple layers ranges from 0.5 nm to 1000 nm.

After step 2 and before step 3, according to the epitaxial quality requirements of step 3, the 2D material intermediate layer in step 2 can be divided into domains by photolithography and other processes to relieve the stress. The domain size can be 1*1 mm² to 1000*1000 mm².

Step 3, growing an epitaxial layer 2 of InGaN-based material on the intermediate layer using van der Waals Epitaxy or quasi-van der Waals Epitaxy technology.

When MoSe₂ or WSe₂ is adopted as the outermost layer of the 2D material of the present disclosure, the lattice constant can be as high as 0.3283 nm or 0.3297 nm, and is highly matched to the InGaN epitaxial layer in the red light emission range. In addition to ensuring the quality of the epitaxial layer, it has the opportunity to simplify the epitaxial and assembly processes, and will also make the selection of substrate materials more widely available.

In the present disclosure, when the substrate material has any chemical composition or micro-defects that may affect the quality of the epitaxy, the 2D material can adopt hetero-structures, and choose a material with strong chemical stability or diffusion barrier performance as the bottom layer, for example hBN, to be bonded to the substrate, and the surface layer is made of a material that matches well with the epitaxial layer.

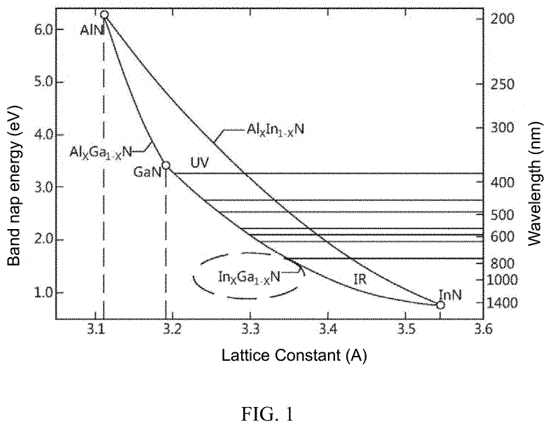

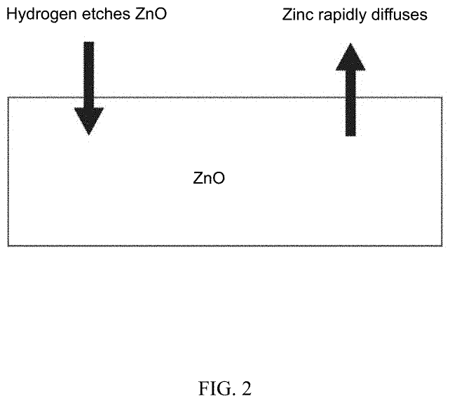

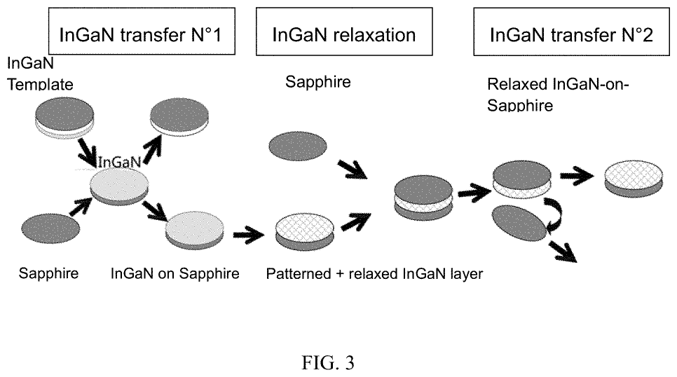

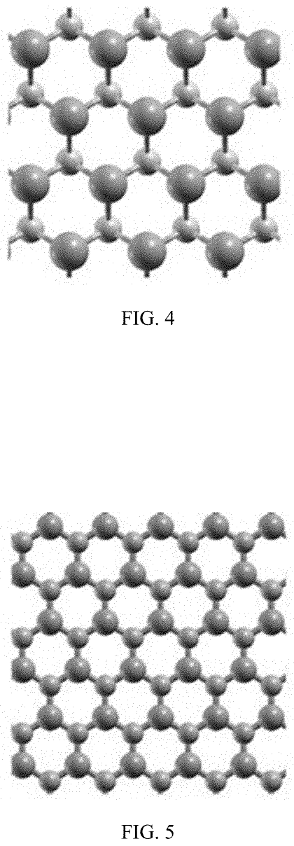

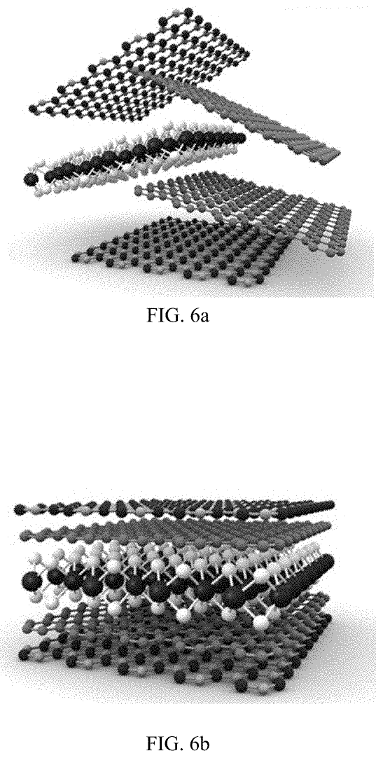

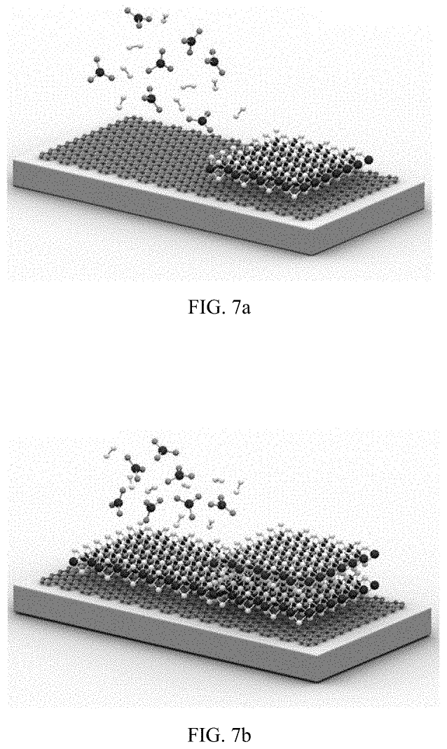

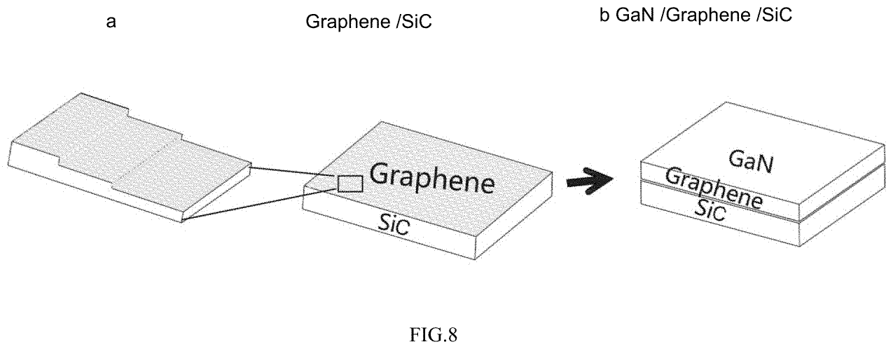

The InGaN template epitaxial growth at the beginning of the InGaN template substrate manufacturing process of French Soitec company already includes the basic material and epitaxial process cost. This part of the cost evaluation is not less than the process cost of the method of the present disclosure; and its follow-up must go through two InGaN layer peeling-bonding processes, and includes stress relaxation lithography as a necessary process. Regardless of the impact of multiple processes on the yield rate, the related processes can significantly increase the manufacturing cost of the finished InGaN template substrate. However, according to the company's announcement, the current upper limit of the lattice constant of its InGaN temple substrate is only 0.3205 nanometers (nm). This lattice constant value is actually only slightly higher than that of GaN, but still significantly lower than the green and red InGaN light emitting range. Judging from the fact that it is still unable to successfully produce robust green light products using GaN directly as the substrate, the company's technical achievements show that increasing the substrate lattice constant has a clear help, but it is obvious that more complicated and longer epitaxial processes are still needed in the production of components to gradually transfer to the appropriate epitaxial active layer, such that the cost of the component manufacturing will be higher. The present disclosure adopts van der Waals Epitaxy or quasi van der Waals Epitaxy technology, and the mismatched stress or strain energy can be relieved to a certain extent. The lattice constant value of the top layer of the substrate can also reach about 0.329 nanometers (nm), which ideally matches the green and red InGaN range of FIG. 1, and it is conducive to a simpler and more robust green and red InGaN light-emitting component process.

The foregoing descriptions are only preferred embodiments of the present disclosure, and are not intended to limit the present disclosure. It should be pointed out that the equivalent changes made by those skilled in the art in accordance with the design ideas of the present disclosure after reading the present specification shall fall within the scope of protection of the present disclosure.

1. A red, green and blue (RGB) full-color InGaN-based light-emitting diode (LED), wherein:
a substrate material is covered with a lattice-matched two-dimensional (2D) material ultra-thin layer on a surface of the substrate material as an intermediate layer,
an InGaN-based material epitaxial layer is grown on the lattice-matched 2D material ultra-thin layer, and
the lattice-matched 2D material ultra-thin layer is formed by a single material or formed by stacking more than one material.

2. The RGB full-color InGaN-based LED according to claim 1, wherein a 2D material of the lattice-matched 2D material ultra-thin layer is hexagonal boron nitride (hBN), graphene, hBNC, WS₂, WSe₂, MoS₂ or MoSe₂.

3. The RGB full-color InGaN-based LED according to claim 1, wherein the lattice-matched 2D material ultra-thin layer has a thickness that ranges from 0.5 nm to 1000 nm.

4. The RGB full-color InGaN-based LED according to claim 1, wherein:
the lattice-matched 2D material ultra-thin layer is a composite layer structure,
a top layer of the composite layer structure is made of a 2D material that matches an InGaN lattice of the InGaN-based material epitaxial layer, and
a bottom layer of the composite layer structure is made of a 2D material with a barrier effect.

5. The RGB full-color InGaN-based LED according to claim 1, wherein the substrate material is sapphire, zinc oxide (ZnO), monocrystalline silicon (Si), SiC, GaN, ceramic or glass.

6. The RGB full-color InGaN-based LED according to claim 1, wherein:
a metal catalytic layer is added between the substrate material and the intermediate layer,
the metal catalytic layer has a total thickness that ranges from 0.5 nm to 3000 nm, and
the metal catalytic layer comprises Fe, Co, Ni, Au, Ag, Cu, W, Mo, Ru or Pt.

7. A method for preparing the RGB full-color InGaN-based LED according to claim 1, wherein epitaxial steps for the InGaN-based material epitaxial layer and the substrate material are as follows:
Step 1, performing epitaxial growth grade polishing on the substrate material, and preparing for subsequent manufacturing procedures through a pre-treatment;
Step 2, covering a lattice-matched 2D material on the surface of the substrate material as the intermediate layer for an epitaxial InGaN material of the InGaN-based material epitaxial layer by using van der Waals epitaxy or quasi-van der Waals epitaxy technology; and
Step 3, growing an epitaxial layer of InGaN-based material on the intermediate layer using the van der Waals epitaxy or the quasi-van der Waals epitaxy technology.

8. The method for preparing the RGB full-color InGaN-based LED according to claim 7, wherein:
in Step 2, a single layer or a composite layer 2D material is covered on the surface of the substrate material, and
a total thickness of the single layer or the composite layer 2D material ranges from 0.5 nm to 1000 nm.

9. The method for preparing the RGB full-color InGaN-based LED according to claim 7, wherein:
between Step 1 and Step 2, the method comprises adding a metal catalytic layer,
a total thickness of the metal catalytic layer ranges from 0.5 nm to 3000 nm, and
the metal catalytic layer is grown or deposited on the surface of the substrate material before Step 2.

10. The method for preparing the RGB full-color InGaN-based LED according to claim 7, wherein:
between Step 2 and Step 3, the method comprises lithographically dividing intermediate layer formed in Step 2 into domains, and
each of the domains has a size from 1*1 mm² to 1000*1000 mm².
